(19) United States
(12) Patent Application Publication
(10) Pub. No.: US 2024/0128246 A1
(43) Pub. Date: Apr. 18, 2024

(54) SEMICONDUCTOR DEVICES AND METHODS OF MAKING SAME

(71) Applicant: TEXAS INSTRUMENTS INCORPORATED, Dallas, TX (US)

(72) Inventors: Kwang-Soo KIM, SUNNYVALE, CA (US); Makoto SHIBUYA, TOKYO (JP); Johan STRYDOM, SARATOGA, CA (US)

(21) Appl. No.: 17/966,530

(22) Filed: Oct. 14, 2022

(51) Int. Cl. H01L 25/16; H01L 21/48; H01L 23/00; H01L 23/498; H02M 3/00

(52) U.S. Cl. CPC H01L 25/16; H01L 21/4853; H01L 23/49844; H01L 24/48; H02M 3/003; H01L 23/49822; H01L 2224/48106; H01L 2224/48137; H01L 2224/48225; H01L 2924/10272; H01L 2924/1033; H01L 2924/1306; H01L 2924/1426; H01L 2924/19041; H01L 2924/30107

(57) ABSTRACT

One example includes an apparatus that includes an insulating layer and an electrically conductive layer on the insulating layer. The conductive layer includes a plurality of electrically isolated and conductive regions. A first switch is on a first of the conductive regions, and the first switch has a first terminal and a second terminal. A second switch is on a second of the conductive regions, and the second switch has a third terminal and fourth terminal. A passive component has a fifth terminal and a sixth terminal. The first and third terminals are coupled to the first conductive region. The fourth and sixth terminals are coupled to the second conductive region. The second and fifth terminals are coupled to a third of the conductive regions.

### TECHNICAL FIELD

This description relates generally to semiconductor devices and methods of making semiconductor devices.

### BACKGROUND

Parasitic inductances, such as those caused by the package of semiconductor devices in power converters, can limit the switching speed of power modules due to increased transient voltages responsive to turning on or off power switches. For example, the transient voltage is proportional to the inductance and the change in current over time (e.g., V≈L*di/dt). The problem exacerbates for high-speed power switching devices, such as GaN or SiC devices, because the increase in switching speed increase the change in current (di/dt).

### SUMMARY

One example described herein provides an apparatus that includes an insulating layer and an electrically conductive layer on the insulating layer. The conductive layer includes a plurality of electrically isolated and conductive regions. A first switch is on a first of the conductive regions, and the first switch has a first terminal and a second terminal. A second switch is on a second of the conductive regions, and the second switch has a third terminal and fourth terminal. A passive component has a fifth terminal and a sixth terminal. The first and third terminals are coupled to the first conductive region. The fourth and sixth terminals are coupled to the second conductive region. The second and fifth terminals are coupled to a third of the conductive regions.

Another example described herein provides a system that includes a substrate and a power converter circuit. The substrate includes an insulating layer having a planar surface and an electrically conductive layer on the insulating layer. The conductive layer includes a plurality of patterned conductive regions, which are electrically isolated from each other. The power converter circuit includes first and second switches, which are coupled in series with the first switch between first and second voltage terminals. The power converter circuit also includes a passive component, which has fifth and sixth terminals, coupled in parallel with the first and second switches between the first and second voltage terminals. The first switch is disposed on a first of the conductive regions, and the first switch has first and second terminals. The second switch is disposed on a second of the conductive regions, and the second switch has third and fourth terminals. The first terminal and the third terminal are coupled to the first conductive region. The fourth terminal, the sixth terminal and the second voltage are coupled to the second conductive region. The second terminal, the fifth terminal and the first voltage terminal are coupled to a third of the conductive regions.

Another example described herein includes a method. The method includes forming a first, second and third patterned conductive regions in a conductive layer so the first conductive region surrounds the third conductive region, and the conductive regions are electrically isolated from each other. The conductive layer is over an insulating substrate layer. The method also includes placing a first switch on the first conductive region, the first switch having first and second terminals and a first control terminal. The method also includes placing a second switch on the second conductive region, the second switch having third and fourth terminals and a second control terminal. The method also includes placing a passive component, having fifth and sixth terminals, on the conductive layer. The passive component has a body portion that extends as a jumper over a portion of a gap between the second and first conductive regions and over a portion of a gap between the first and third conductive regions. The fifth and sixth terminals are coupled to the second and third conductive regions, respectively. The method also includes coupling the first terminal and the third terminal to the first conductive region. The method also includes coupling the fourth terminal to the second conductive region, and coupling the second terminal to the third conductive region.

### BRIEF DESCRIPTION OF THE DRAWINGS

FIG. 1 is a block diagram of an example power circuit configured to implement a half bridge.

FIG. 2 is a top view of semiconductor device showing an example layout of components.

FIG. 3 is a side sectional view of the semiconductor device of FIG. 2 taken along line 3-3 in FIG. 2.

FIG. 4 is an isometric view shown an example semiconductor device with encapsulation removed.

FIG. 5 is a top view of part of a semiconductor device showing example circuit paths.

FIG. 6 is a top view of semiconductor device showing another example layout of components.

FIG. 7 is a top view of semiconductor device showing yet another example layout of components.

FIG. 8 is a flow diagram showing an example method of making a semiconductor device.

### DETAILED DESCRIPTION

This description relates generally to a semiconductor device having a patterned conductive substrate and components configured and arranged on the substrate to provide a circuit, such as an integrated power circuit.

As an example, a semiconductor device includes a substrate having an insulating layer and an electrically conductive layer on the insulating layer. The conductive layer includes a plurality of electrically conductive regions. For example, the conductive regions can be patterned in the conductive layer to have a respective periphery, in which peripheries of adjacent conductive regions are spaced apart to electrically isolate the respective conductive regions from each other across the insulating layer. The substrate can be implemented as a direct bonded copper substrate to increase thermal performance of semiconductor device. The semiconductor device can also achieve a low parasitic inductance by configuring and arranging components on the substrate, as described herein.

For example, the semiconductor device includes a first switch on a first of the conductive regions and a second switch on a second of the conductive regions. The switches can be implemented as transistors (e.g., power transistors, such as field effect transistors (FETs)) of respective IC die. The first switch (e.g., FET) can be mounted on a first conductive region and the second switch (e.g., another FET) can be mounted on a second conductive region. The semiconductor device can also include a passive component (e.g., one or more decoupling capacitors) mounted across multiple conductive regions. For example, the passive component includes one terminal coupled to the second conductive region and another terminal coupled to a third conductive region. There can be one or more passive components coupled (e.g., in parallel) between the second and third conductive regions.

Respective terminals of the first and second switches can also be coupled to the first and second conductive regions. In the example where the switches are FETs, the source of the first FET and the drain of the second FET are coupled to the first conductive region (e.g., by one or more respective wires). The drain of the first FET can be coupled to the third conductive region, and the source of the second FET is coupled to the second conductive region (e.g., by one or more respective wires). In an example, the third conductive region is completely surrounded by the first conductive region, such as to form an island region on the substrate in which the drain region of the first FET surrounds the source region of the first FET. Additionally, the second conductive region can partially surround the first conductive region, so the source region of the second FET partially surrounds the source region of the first FET.

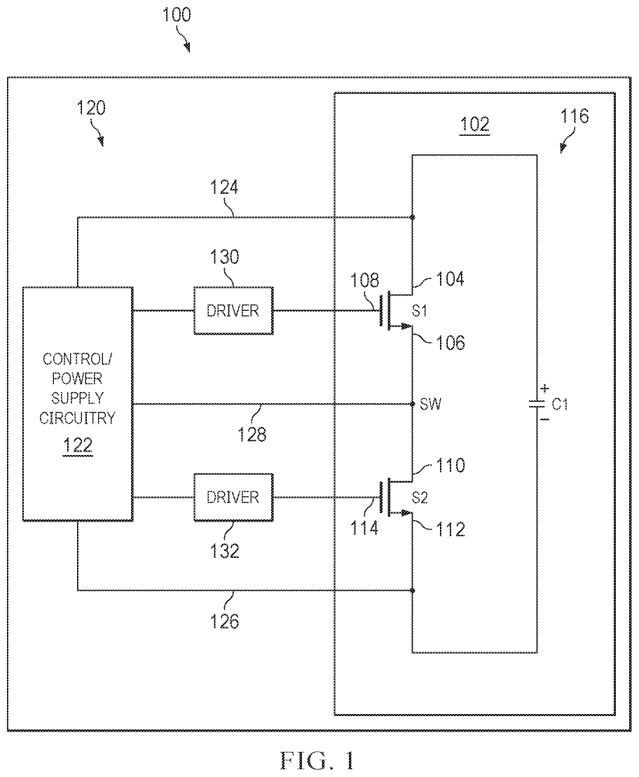

FIG. 1 is a block diagram of an example circuit 100 configured to implement a power converter (e.g., a buck regulator, a boost regulator, a buck-boost regulator or other regulator) depending on application needs. In the example of FIG. 1, the circuit 100 includes a semiconductor device 102 that includes first and second switches S1 and S2. As shown in FIG. 1, the switches S1 and S2 are field effect transistors (FETs). In the semiconductor device 102, the switches S1 and S2 can be implemented as high-speed power FETs, such as GaN or SiC FETs. The first switch S1 has terminals 104 and 106 and a control input terminal 108. Similarly, the second switch has terminals 110 and 112 and a control input terminal 114. The switches S1 and S2 can be transistors, such as power transistors. The terminals 106 and 110 are coupled together, such as to provide a switched output (SW) for the semiconductor device 102.

One or more passive components, shown as a decoupling capacitor C1, can be coupled between switch terminals 104 and 112. In an example, a pair of decoupling capacitors, which have the same capacitance, are coupled in parallel between terminals 104 and 112. The decoupling capacitor C1 is configured to isolate the respective voltages at terminals 104 and 112.

The circuit 100 also includes a power/control system 120. The power/control system 120 can be implemented on one or more IC die or on a printed circuit board containing one or more IC die and/or an arrangement of discrete components. For example, the power/control system 120 includes control and power circuitry 122 configured to supply electrical power and to control the switches S1 and S1. The control and power circuitry 122 has a first voltage terminal 124 coupled to the terminal 104 and a second voltage terminal 126 coupled to the terminal 112. The control and power circuitry 122 is configured to supply an output voltage at 124 (e.g., a DC supply voltage), and the terminals 126 and 112 can be ground terminals for the circuit 100. The control and power circuitry 122 also has an input terminal 128 coupled to the switching terminal SW, such as for sensing an output voltage at the terminal SW (e.g., a switching output voltage), which results from operation of the switches S1 and S2.

As a further example, the power/control system 120 includes drivers 130 and 132. In the example where switches S1 and S2 are FETs, the drivers 130 and 132 can be implemented as gate drivers. The control and power circuitry 122 can include control logic (not shown) having control outputs coupled to inputs of the drivers. The control and power circuitry 122 can implement one or more control loops provide control signals (e.g., pulse-width modulated signals) to control the drivers 130 and 132 for commanding an increase or decrease in output power (e.g., voltage and/or current). The drivers 130 and 132 are configured to supply drive signals at the respective control input terminals 108 and 114 responsive to the control signals for controlling the switches S1 and S2. For example, the power switches S1 and S2 are configured as a half-bridge 116, in which S1 is the high-side switch and S2 is the low-side switch, to provide a switching voltage at SW responsive to drive signals received at respective input terminals 108 and 114.

As described herein, the semiconductor device 102 includes a conductive layer patterned on a substrate to provide a plurality of electrically isolated conductive regions. For example, each switch S1 and S2 is implemented as respective IC die. The switch S1 is mounted on a first of the conductive regions and the switch S1 is mounted on a second of the conductive regions. The terminals 104, 106 and 108 of S1 and the terminals 110, 112 and 114 of S2 can be on a surface of the IC die that is spaced apart from and opposite the respective region of the conductive layer where the die are mounted. The terminals 106 and 110 can be coupled by wires (e.g., bondwires) to the first conductive region where S1 is mounted. The terminal 112 and a respective terminal (e.g., a negative terminal) of capacitor C1 can be coupled by wires (e.g., bondwires) to the second conductive region where S2 is mounted. The terminal 104 and the other terminal (e.g., a positive terminal) of capacitor C1 can be coupled by wires (e.g., bondwires) to the a third of the conductive regions. In an example, the third conductive region is completely surrounded by the first conductive region and spaced apart therefrom by the respective gap between the first and third conductive regions. In another example, the second conductive region partially surrounds the second conductive region.

This arrangement enables a compact arrangement of circuitry that forms a power loop on the device 102 having reduced inductance compared to many existing designs. The reduced inductance also allows for faster switching speeds to be used, which can be realized by implementing the switches S1 and S2 using GaN or SiC semiconductor technologies. Thus, the circuit, including the semiconductor device 102 and the power/control system 120, can be integrated within packaging material as a system on chip (SOC) configured to implement an integrated power module that includes a half-bridge circuit formed by S1 and S2 and associated control circuitry. In another example, the semiconductor device 102 can be integrated within packaging material as an SOC configured to implement an integrated half-bridge circuit formed by S1 and S2 and C1. The circuit 100 can configured as a single in-line package power module. Other package configurations can also be used.

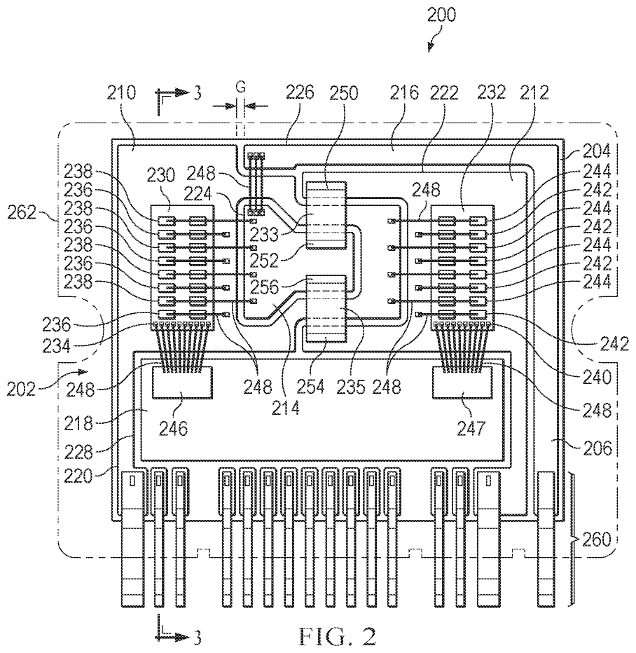

As an example FIGS. 2, 3 and 4 depict examples of a semiconductor device 200, such as can be used to implement the semiconductor device 102 of FIG. 1. The device 200 includes a multi-layer substrate 202. The substrate includes an insulating layer 204 and an electrically conductive layer 206 disposed on a surface the insulating layer 204. A second conductive layer 208 can also be disposed on another surface of the insulating layer opposite the conductive layer 206. The conductive layers 206 and 208 can include copper, gold, aluminum, or other electrically conductive material. The conductive layer 206 includes a plurality of electrically isolated conductive regions 210, 212, 214, 216 and 218. The number and/or shape of the conductive regions 210, 212, 214, 216 and 218 can vary depending on the type and configuration of circuitry being implemented on the semiconductor device 200.

In an example, the substrate 202 is a direct bonded copper (DBC) substrate, in which the insulating layer 204 is a ceramic layer (e.g., alumina or alumina nitride), and the layers 206 and 208 are copper. The layers 206 and 208 can be bonded respective sides of the insulating layer by a high-temperature oxidation process. For example, the DBC substrate layers 204, 206 and 208 are heated to a controlled temperature in an atmosphere of nitrogen containing about 30 ppm of oxygen and a copper-oxygen eutectic forms to bond both to copper and the oxides used as substrates. The conductive layer 206 can be patterned and etched to form the conductive regions 210, 212, 214, 216 and 218. The layer 208 on the opposite side of the insulating layer 204 is usually not patterned and can remain a plain a solid sheet (e.g., without patterning).

Each of the conductive regions 210, 212, 214, 216 and 218 of the layer 206 has a respective periphery (e.g., outer edge) 220, 222, 224, 226 and 228 that is spaced apart from the periphery of at least one other conductive region. The distance between peripheries 220, 222, 224, 226 and 228 of adjacent conductive regions 210, 212, 214, 216 and 218 provides a gap, shown at G, which provides electrical isolation among the conductive regions. The gap G can be uniform between respective conductive regions 210, 212, 214, 216 and 218 or the gap between adjacent peripheries can vary.

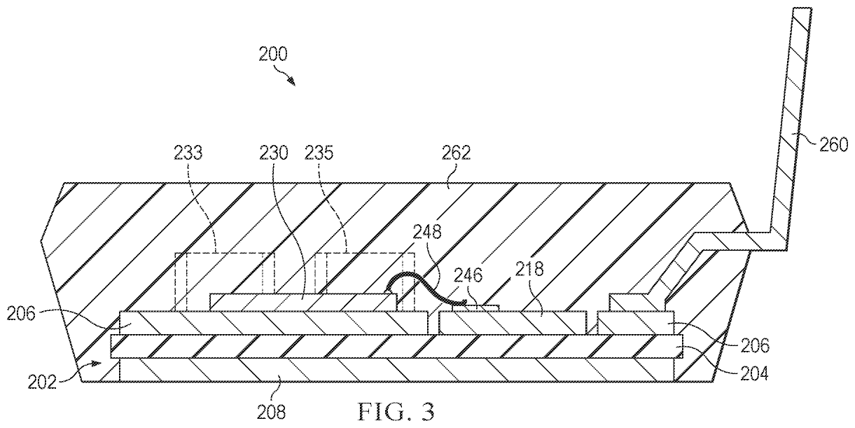

The semiconductor device 200 includes switches 230 and 232 and one or more passive components 233 and 235 arranged and configured on an exposed (e.g., upper) surface of the conductive layer 206 to form a circuit, such as the half-bridge 116 shown in FIG. 1. In the example of FIGS. 2 and 3, the switch 230 is mounted on the conductive region 210 and switch 232 is mounted on the conductive region 212, such as near a center of the regions spaced inwardly from the peripheries 220 and 222, respectively. For example, each of the switches 230 and 232 can be fabricated to provide respective semiconductor die having one or more transistors, such as FETs (e.g., GaN or SiC FETs). The die containing the switches (e.g., FETs) 230 and 232 can be mounted on surfaces by an adhesive (e.g., a die attach adhesive, such as an epoxy, acrylic or acrylate) or other form of attachment.

In an example, the conductive region 210 surrounds the conductive region 214, such as to form an island region on the substrate. For example, the conductive region 210 is implemented as a high-side source region and the conductive region 214 is implemented as a high-side drain for the FET 230. Thus, the source region surrounds the drain region of the FET 230. Additionally, the conductive region 212 can partially surround the conductive region 210. Continuing with the example where the switches 230 and 232 are FETs, the source region of the FET 232 partially surrounds the source region of the other FET 230, such as shown in FIG. 2. The circumscribing arrangement of conductive regions 210, 212 and 214 enables electrical interconnects used to form the circuit on the semiconductor device 200.

Each of the switches 230 and 232 includes an arrangement of conductive terminals, including a control terminal configured to control (e.g., turn on or off) the switch. For the example where each switch 230 and 232 is a die containing one or more FETs, each die has gate, source and drain terminals, such as conductive pads located on an upper surface of the die that is opposite of the surface coupled to the conductive layer 206. Each die thus can include a plurality of gate terminals, source terminals and drain terminals. An increased number of terminals provides a greater number of thermal dissipation paths, which enables higher current capabilities for each die. For example, the switch 230 has an arrangement of gate terminals 234, source terminals 236 and drain terminals 238, and the switch 232 also has an arrangement of gate terminals 240, source terminals 242 and drain terminals 244. The source terminals 236 of switch 230 are coupled to the conductive region 210, and the drain terminals 238 are coupled to the conductive region 214. The source terminals 242 of switch 232 are coupled to the conductive region 212, and the drain terminals 244 are coupled to the conductive region 210. The gate terminals of the switches 230 and 232 are coupled to a respective gate driver 246 and 247. Additional circuitry can be included on each die as well according application requirements. The interconnections between the terminals of switches 230 and 232 and conductive regions 210, 212 and 214 can include respective wires (e.g., bondwires), shown at 248, coupled between the terminals and pins formed on the conductive regions. The cross-sectional thickness of the wires can vary according expected current through the wires. For example, a set of thicker wires 258 are coupled between respective pin patterns of conductive regions 214 and 216, such as to couple the high-side drain to the input power supply for the circuit 200. The wires can be coupled to respective terminals and pins by wedge bonding, ball bonding In other examples, different types of interconnects can be used to couple the terminals and pins formed on the conductive regions. The wires for a given set of terminals can extend in a parallel direction between respective terminals. The number of pads and wires used for each pattern can vary depending on the expected current and power requirements of the circuit 200.

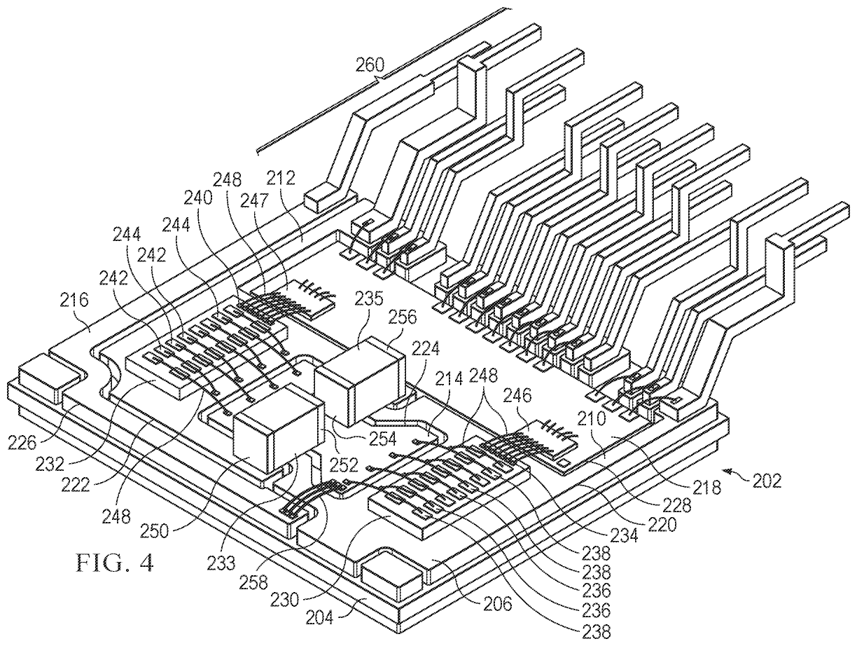

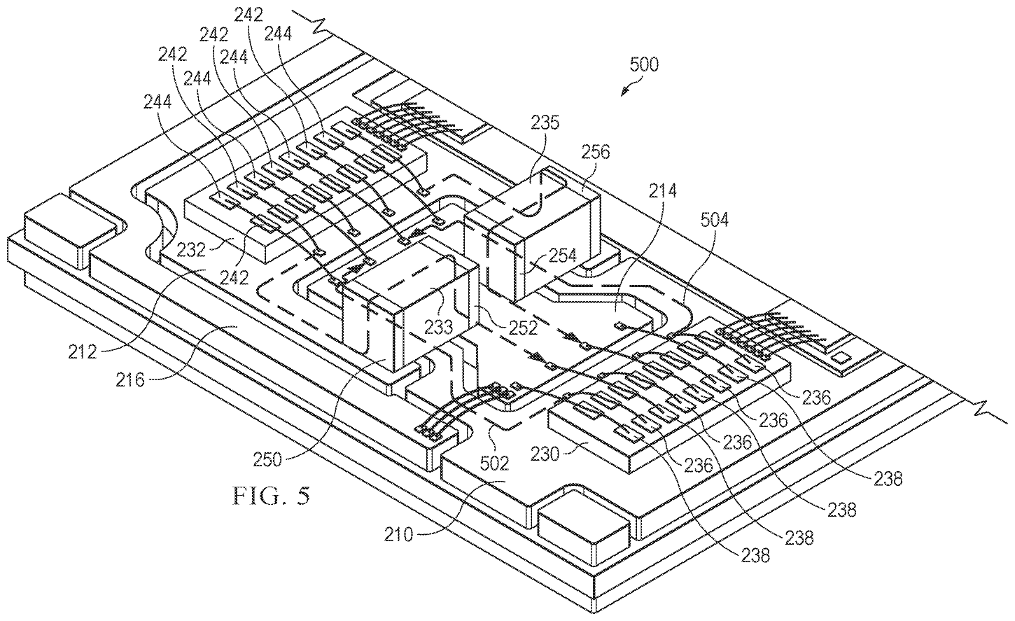

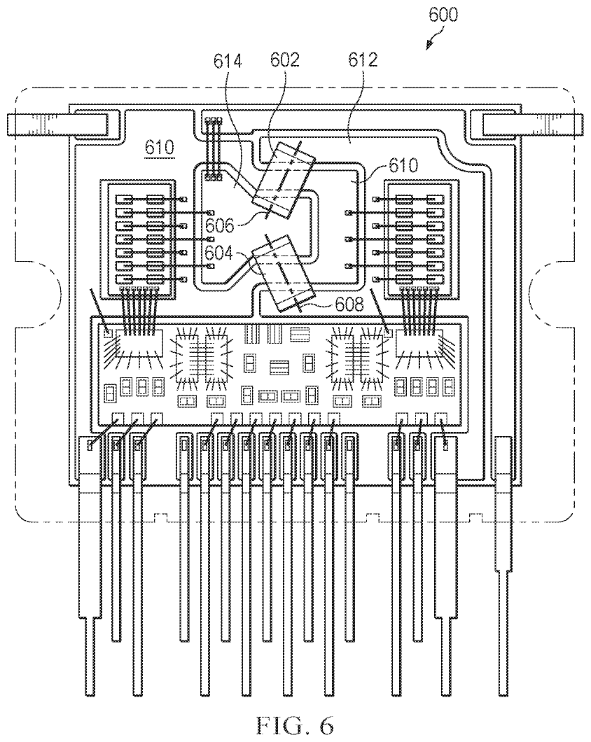

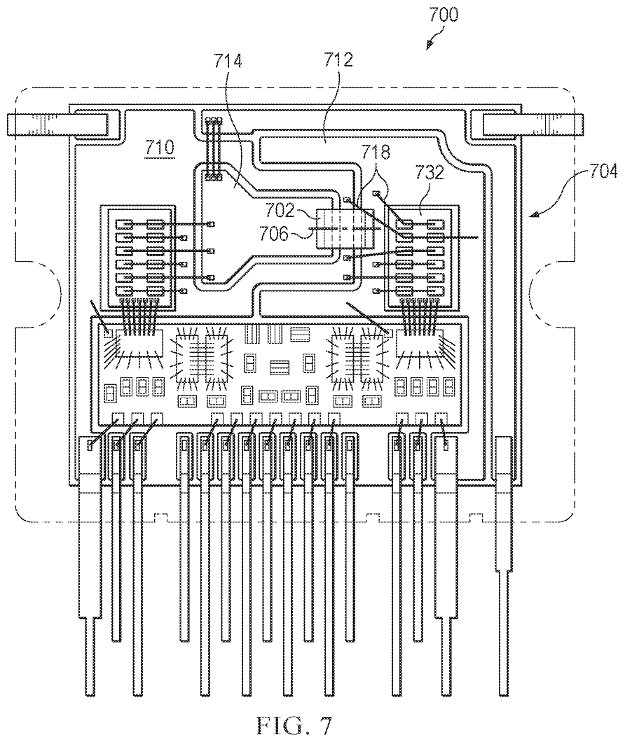

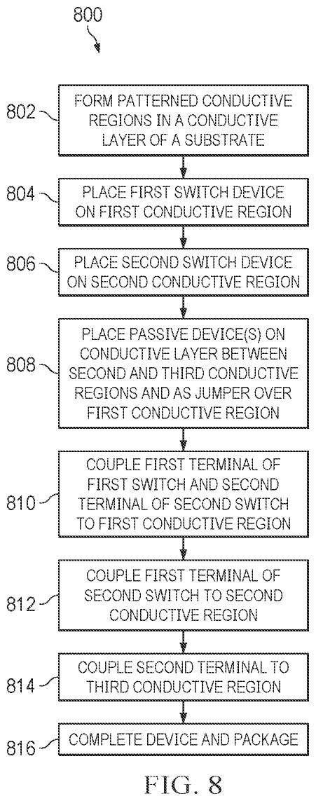

As a further example, each of the passive components 233 and 235 is coupled between conductive regions 212 and 214. For the example of implementing the circuitry to provide a half-bridge circuit, each passive components 233 and 235 is a capacitor. Other types of one or more passive components can be used in other examples. The capacitor 233 has terminals 250 and 252 and a body portion extending between the terminals. The capacitor 235 also has terminals 254 and 256 and a body portion extending between the terminals. The terminals of the capacitors 233 and 235 are coupled to respective plates of the capacitor. As shown in FIGS. 2 and 4, the terminals 250 and 254 are coupled (e.g., bonded) to the conductive region 212 and the other terminal is coupled to the conductive region 214. The body portion of each capacitor 233 and 235 extends as a jumper over a portion of the gap between the conductive regions 212 and 210, over a portion of the conductive region 210 and over a portion of the gap between the conductive regions 210 and 214. The body portions can have an external insulating layer (e.g., a coating) to electrically isolate the body portion from the conductive layer (e.g., conductive regions 210, 212 and 214). By using the capacitors 233 and 235 as jumpers in such a configuration, current flow between the terminals 236 and 244 travels along a path through the conductive region 210 having a direction that is transverse to (e.g., and below) a longitudinal direction of the body portion of the respective capacitors 233 and 235. Also, the electrical path of the circuit (e.g., a half-bridge circuit) implemented on the semiconductor device 200 can form two FIG. 8 shaped paths, such as shown in FIG. 5. The angle between the longitudinal direction of the capacitor body portions relative to the portions of the conductive region 210 and peripheries over which the body portion extends can vary from that shown (see, e.g., FIGS. 6 and 7). The relative angle further can be a design parameter for the circuit 200.

The semiconductor device 200 further can include leads 260 which are coupled to the respective conductive regions 210, 212, 214, 216 and 218. In the example of FIGS. 2, 3 and 4, the leads 260 are shown a row of elongated parallel pins arranged along and extending in a desired pin pattern from a given side of the semiconductor device 200, such as to implement a single in-line package power module. In another example, the leads 260 could be formed along more than side of the package or the semiconductor device can be a leadless device (e.g., quad flat no-lead) having pads or balls for surface mount. For example, the leads 260 can provide electrical connections to various terminals of the circuit, such as for communicating power and control signals.

As shown in FIG. 2, the circuitry on the substrate 202 (e.g., switches 230, 232, capacitors 233, 235, wires 248 and 258, etc.) and the substrate 202 itself are encapsulated by a packaging material 262 to form an SOC. The packaging material may be an epoxy molding compound, magnetic molding compound, polyimide, metal, plastic, glass, ceramic, etc. The leads 260 can extend from or otherwise be accessible for connecting to an external circuit (e.g., power/control system 120), such as can be provided on printed circuit board or other substrate.

FIG. 5 is an enlarged isometric top view of part of the semiconductor device 200 shown in FIG. 4. Accordingly, the description of FIG. 5 also refers to FIGS. 2, 3 and 4. FIG. 5 schematically shows examples of respective circuit paths 502 and 504 for a half bridge circuit. Each path 502, 504 thus passes through circuit components (e.g., switches 230, 232 and capacitors 233 and 235) and conductive regions (e.g., conductive regions 210, 212 and 214). As shown in FIG. 5, starting at terminal 236, the path 502 goes from terminal 236 (e.g., a source of high-side FET 230) through respective wires 248 to the conductive region 210 through respective wires to another terminal 244 (e.g., drain of low-side FET 232). From the terminal 244, the path 502 travels through the low-side FET to another terminal 242 (e.g., source of low-side FET 232). From the terminal 242, the path 502 travels along the conductive region 212 to the capacitor terminal 250 and through the capacitor to the other terminal 252, which is coupled to the conductive region 214. From the terminal 252, the path 502 travels along the conductive region 214 to one or more terminals connected by wires 248 to terminals 238 (e.g., high-side drain terminals) and through the high-side FET back to the terminal 236.

The other path 504 is a similar to the path 502 but travels along different portions of the respective conductive regions 210, 212 and 214 and through the other capacitor 235. For example, starting at terminal 236 along a side of the switch closer to the leads 260, the path 504 goes from terminal 236 (e.g., a source of high-side FET 230) through respective wires 248 to the conductive region 210 through respective wires to another terminal 244 (e.g., drain of low-side FET 232). From the terminal 244, the path 502 travels through the low-side FET to another terminal 242 (e.g., source of low-side FET 232). From the terminal 242, the path 502 travels along the conductive region 212 to the capacitor terminal 254 and through the capacitor 235 to the other terminal 256, which is coupled to the conductive region 214. From the terminal 256, the path 504 travels along the conductive region 214 to one or more terminals connected by wires 248 to terminals 238 (e.g., high-side drain terminals) and through the high-side FET back to the terminal 236. Each of the paths thus makes a figure 8-shaped path through the device. Each path includes a path portion through a capacitor 233, 235 that extends over portion of the conductive region 210 surrounding the conductive region 214.

FIGS. 6 and 7 are plan views of semiconductor devices showing examples of some different configuration for passive devices (e.g., capacitors). In each of FIGS. 6 and 7, the substrate and circuitry provided thereon can be configured as described herein with respect to FIGS. 1-5 and 8. In the example of FIG. 6, the semiconductor device 600 includes two passive devices 602 and 604 coupled in parallel between conductive regions 612 and 614. Each of the passive devices 602 and 604 has a body portion extending in a longitudinal direction, shown at 606 and 608, respectively, between end terminals. The body portions of the passive devices extend as a jumper over a portion of the conductive region 610, which surrounds conductive island region 614. In the example of FIG. 6, the directions 606 and 608 of the respective body portions are angled relative to a direction of the conductive portion 210 over which the body portions extend. The relative angles can vary over a range of angles (e.g., =/−45 degrees), such as according to on design and application requirements. The adjacent end terminals of the passive devices are thus coupled to opposite side portions of the conductive region 614 and to the laterally extending arms of the conductive region 612, which partially surround the conductive region 614.

FIG. 7 shows and other example semiconductor device 700 that includes a single passive device (e.g., capacitor) 702 mounted to a substrate 704. In the example, of FIG. 7, the passive device 702 has a body portion extending in a longitudinal direction, shown at 706, between end terminals thereof. The body portion of the passive device 702 extends between conductive regions 712 and 714 and as a jumper over a portion of the conductive region 710, which surrounds conductive island region 714. Also, in some examples, wires 718 for coupling terminals of the switch 732 with respective conductive regions 710 and 712 can be moved (compared to FIGS. 2, 4 and 6) to accommodate the placement of the passive device 702.

In view of the foregoing structural and functional features described above, a method that can be implemented to make a semiconductor device is shown in FIG. 8. While, for purposes of simplicity of explanation, the method of FIG. 8 is shown and described as executing serially, systems and methods described herein are not limited by the illustrated order, as some actions could occur in different orders, multiple times and/or concurrently from that described herein. For example, FIG. 8 is a flow diagram depicting an example method 800 that can be used to make a semiconductor device, such as an integrated SOC power supply.

At 802, the method includes forming a plurality of conductive regions in a conductive layer of a substrate. For example, the substrate is a DBC substrate 202 and the conductive regions 210, 212, 214, 216 and 218 are formed by patterning and etching the respective regions in a copper layer of the substrate. As described herein, the first, second and third conductive regions 210, 212 and 214 can be formed so the conductive region 210 completely surrounds the conductive region 214 (e.g., the region 214 is an island region of conductive material). Also, the conductive regions are electrically isolated from each other.

At 804, a first switch is placed on the first conductive region. For example, the first switch is a transistor, such as a FET (e.g., GaN or SiC FET) 230, formed on a die and the die is mounted to the conductive region 210. The first switch thus has switch terminals and a control terminal (e.g., bond pads) which are accessible on the die.

At 806, a second switch is placed on the second conductive region. For example, the second switch is a transistor, such as a FET (e.g., GaN or SiC FET) 232, formed on another die and the die is mounted to the conductive region 212. The second switch thus has first and second switch terminals (e.g., source and drain terminals, respectively) and a control terminal (e.g., a gate terminal) which are accessible as bond pads on the die implemented as the switch 232.

At 808, a passive component is placed on the conductive layer. The passive component includes terminals and a body portion that extends between the ends. The passive component can be a bus capacitor configured to decouple respective voltage rails of the half-bridge circuit being formed by the method 800. For example, the passive component 233, 235 is placed on the conductive layer 206, and the body portion provides a jumper over a portion of a gap between the second and first conductive regions 212 and 210, respectively, and over a portion of a gap between the first and third conductive regions 210 and 214, respectively. The terminals 250 and 252 can be coupled (e.g., by soldering or a conductive adhesive) to the second and third conductive regions 212 and 214, respectively.

At 810, the first terminal of the first switch and the second terminal of the second switch are coupled to the first conductive region. For example, wires (e.g., bondwires) 248 are used to couple one or more source terminals 236 of the FET 230 to the conductive region 210. Additional wires 248 are used to couple the drain terminal 244 of the FET 232 to the first conductive region 210. An output terminal can be coupled to the first conductive region 210 (e.g., by respective wires) to supply a switching output voltage responsive to operation of the FETs 230 and 232.

At 812, the first terminal of the second switch is coupled to the second conductive region. For example, wires (e.g., bondwires) 248 are used to couple one or more source terminals 242 of the switch (e.g., FET) 232 to the conductive region 212.

At 814, the second terminal of the first switch is coupled to the third conductive region. For example, wires (e.g., bondwires) 248 are used to couple one or more drain terminals 238 of the switch (e.g., FET) 230 to the conductive region 214.

As mentioned, the connections provided by the bond wires can thus configure the first switch, the second switch and passive component(s) as a half-bridge or other circuitry depending on application requirements. At 816, the connections for the circuitry being fabricated can be completed, such as to couple each of the conductive regions to respective leads by additional wires between pin pad patterns. After the connections have been completed, the method can include packaging the device in a packaging material to provide an integrated system on chip (SOC), such as described herein.

The semiconductor devices, systems methods described herein are able to achieve lower loop inductances than many existing devices. The low inductances allow GaN or SiC processes to be used, which can result in improved switching and/or thermal properties. The improved thermal and electrical performances further enable greater power output to be realized than many existing designs. As an example, by using the proposed layout for conductive regions configured in a manner described herein and using a DBC substrate, devices can realize higher thermal performance and lower stray inductance than many existing designs.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. An apparatus comprising:
an insulating layer;
an electrically conductive layer on the insulating layer, the conductive layer including a plurality of electrically isolated and conductive regions;
a first switch on a first of the conductive regions, the first switch having a first terminal and a second terminal;
a second switch on a second of the conductive regions, the second switch having a third terminal and fourth terminal; and
a passive component having a fifth terminal and a sixth terminal,
wherein the first and third terminals are coupled to the first conductive region, the fourth and sixth terminals are coupled to the second conductive region, and the second and fifth terminals are coupled to a third of the conductive regions.

2. The apparatus of claim 1, wherein each of the conductive regions has a periphery, which is spaced from the periphery of at least one other of the conductive regions by a gap.

3. The apparatus of claim 2, wherein the third conductive region is completely surrounded by the first conductive region and spaced apart therefrom by the respective gap between the first and third conductive regions.

4. The apparatus of claim 3, wherein the passive component is a first passive component, the apparatus comprising a second passive component coupled in parallel with the first passive component between the second and third conductive regions.

5. The apparatus of claim 3, wherein the first switch comprises a first field effect transistor (FET) implemented on a first die, which is mounted on the first conductive region, and the second switch comprises a second FET implemented on a second die, which is mounted on the second conductive region, the first FET and the second FET configured as a half-bridge circuit, in which the first FET is a high-side FET of the half-bridge circuit and the second FET is a low-side FET of the half-bridge circuit,
the first terminal is a drain of the high-side FET and the second terminal is a source of the high-side FET, whereby the third conductive region coupled to the high-side drain is surrounded by the first conductive region coupled to the high-side source.

6. The apparatus of claim 3, wherein the passive component is a decoupling capacitor having a body portion, which includes plates of the capacitor, in which the fifth and sixth terminals are coupled to the respective plates of the capacitor on opposing sides of the body portion, and the body portion extends as a jumper over a portion of the gap between the first and second conductive regions and over a portion of the gap between the first and third conductive regions.

7. The apparatus of claim 6, wherein current flow between the first and third terminals travels along a path through the first conductive region having a direction transverse to a direction along which the body portion of the capacitor extends.

8. The apparatus of claim 1, further comprising:
a first wire coupled between the first terminal and the first conductive region;
a second wire coupled between the second terminal and the third conductive region;
a third wire coupled between the third terminal and the first conductive region; and
a fourth wire coupled between the fourth terminal and the second conductive region.

9. The apparatus of claim 8, wherein the first and second wires bonds are parallel, and the third and fourth wires are parallel.

10. The apparatus of claim 1, wherein the first switch comprises a first transistor die, which is mounted on the first conductive region, and second switch comprises a second transistor die mounted on the second conductive region.

11. The apparatus of claim 10, wherein:
the first transistor die comprises a first field effect transistor (FET), in which the first terminal is a drain of the first FET and the second terminal is a source of the first FET, and
the second transistor die comprises a second FET, in which the third terminal is a drain of the second FET and the fourth terminal is a source of the second FET.

12. The apparatus of claim 11, wherein the first and second FETs are one of gallium nitride or silicon carbide FETs.

13. The apparatus of claim 10, wherein the conductive layer and the insulating layer form at least part of a direct bonded copper substrate, and the apparatus is a system on chip (SOC).

14. A system comprising:
a substrate comprising:
an insulating layer having a planar surface;
an electrically conductive layer on the insulating layer, the conductive layer including a plurality of patterned conductive regions, which are electrically isolated from each other;
a power converter circuit comprising:
a first switch disposed on a first of the conductive regions, the first switch having first and second terminals,
a second switch disposed on a second of the conductive regions, the second switch having third and fourth terminals, the second switch is coupled in series with the first switch between first and second voltage terminals; and
a passive component having fifth and sixth terminals, the passive component is coupled in parallel with the first and second switches between the first and second voltage terminals, wherein:
the first terminal and the third terminal are coupled to the first conductive region,
the fourth terminal, the sixth terminal and the second voltage are coupled to the second conductive region, and
the second terminal, the fifth terminal and the first voltage terminal are coupled to a third of the conductive regions.

15. The system of claim 14, wherein the power converter circuit has an output terminal coupled to the first conductive region, the first switch has a first control terminal and the second switch has a second control terminal, the system further comprising:
a power/control system having first and second control output terminals coupled to the first and second control terminals, respectively, the power/control system configured to control the first and second switches to provide a voltage at the output terminal of the power converter circuit.

16. The system of claim 15, wherein the system is a system on chip (SOC) comprising the substrate, the power converter circuit and the power/control system.

17. The system of claim 14, wherein the third conductive region is completely surrounded by the first conductive region and spaced apart therefrom by a gap between respective peripheries of the first and third conductive regions.

18. The system of claim 17, wherein the first switch comprises a first field effect transistor (FET) implemented on a first die, which is mounted on the first conductive region, and the second switch comprises a second FET implemented on a second die, which is mounted on the second conductive region, the first FET and the second FET are configured as a half-bridge circuit, in which the first FET is a high-side FET of the half-bridge circuit and the second FET is a low-side FET of the half-bridge circuit,
the first terminal is a drain of the high-side FET and the second terminal is a source of the high-side FET, whereby the third conductive region is coupled to the high-side drain and surrounded by the first conductive region that is also coupled to the high-side source.

19. The system of claim 17, wherein the passive component is a first capacitor, the apparatus comprising a second capacitor coupled in parallel with the first capacitor between the second and third conductive regions, each of the first and second capacitors having a body portion that extends as a jumper over a portion of a gap between the second and first conductive regions and over a portion of the gap between the first and third conductive regions.

20. A method comprising:
forming a first, second and third patterned conductive regions in a conductive layer so the first conductive region surrounds the third conductive region and the conductive regions are electrically isolated from each other, the conductive layer being over an insulating substrate layer;
placing a first switch on the first conductive region, the first switch having first and second terminals and a first control terminal,
placing a second switch on the second conductive region, the second switch having third and fourth terminals and a second control terminal; and
placing a passive component, having fifth and sixth terminals, on the conductive layer, the passive component having a body portion that extends as a jumper over a portion of a gap between the second and first conductive regions and over a portion of a gap between the first and third conductive regions, the fifth and sixth terminals being coupled to the second and third conductive regions, respectively;
coupling the first terminal and the third terminal to the first conductive region;
coupling the fourth terminal to the second conductive region; and
coupling the second terminal to the third conductive region.

21. The method of claim 20, wherein the first switch, the second switch and the passive component are configured as a half-bridge, the method further comprising packaging the device in a packaging material to provide an integrated system on chip (SOC).
